(19) United States
(12) Patent Application Publication
(10) Pub. No.: US 2008/0067545 A1
(43) Pub. Date: Mar. 20, 2008

(54) Semiconductor device including field effect transistor and method of forming the same

(75) Inventors: Hwa-sung Rhee, Seongnam-si (KR); Tetsuji Ueno, Suwon-si (KR); Ho Lee, Cheoan-si (KR); Myung-sun Kim, Hwaseong-si (KR); Ji-hye Yi, Suwon-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/898,978

(22) Filed: Sep. 18, 2007

(30) Foreign Application Priority Data
Sep. 20, 2006 (KR) 10-2006-91356

(51) Int. Cl. H01L 29/778; H01L 21/336

(52) U.S. Cl. 257/190; 438/300; 257/E21.403; 257/E29.246

(57) ABSTRACT

A semiconductor device having a field effect transistor according to example embodiments may include a first semiconductor pattern disposed to fill a first recess region and a second semiconductor pattern disposed to fill a second recess region. The first recess region may be shallower than the second recess region and may be disposed adjacent to a channel region. Thus, sufficient stress may be supplied to the channel region to increase the mobility of holes or carriers in a channel and enhance a punchthrough characteristic.

### PRIORITY STATEMENT

This U.S. non-provisional patent application claims priority under 35 U.S.C §119 to Korean Patent Application 10-2006-0091356, filed on Sep. 20, 2006 in the Korean Intellectual Property Office (KIPO), the entire contents of which are hereby incorporated by reference.

### BACKGROUND

Example embodiments relate to semiconductor devices and methods of forming the same. Example embodiments also relate to a semiconductor device including a field effect transistor and a method of forming the same. A field effect transistor (hereinafter referred to as “transistor”) may be an important element in a semiconductor device. A conventional transistor may include a source region and a drain region formed on a semiconductor substrate and spaced apart from each other. A gate electrode may be disposed to cover the top of a channel region between the source and drain regions. The formation of the source and drain regions may be performed by implanting dopant ions into the substrate. The gate electrode may be insulated from the channel region by a gate oxide layer interposed between the substrate and the gate electrode. Such a transistor may be used as a single element constituting a switching device and/or a logic circuit in a semiconductor device.

With the trend toward higher integration levels for semiconductor devices, transistors may experience various problems caused by the decrease in channel length of a transistor. For example, the characteristics of the transistor may be degraded; a punchthrough characteristic between the source and drain regions may be degraded; and the turn-on current of the transistor may be decreased. A decrease in the turn-on current may cause the operating speed of the transistor to be reduced. Consequently, the operating speed of the semiconductor device may also be reduced.

### SUMMARY

Example embodiments relate to a semiconductor device and a method of forming the same. A semiconductor device according to example embodiments may include a gate pattern on a semiconductor substrate, the semiconductor substrate doped with a first-type dopant; a first semiconductor pattern in the semiconductor substrate, the first semiconductor pattern supplying a compressive or tensile-force to a channel region below the gate pattern; and/or a second semiconductor pattern in the semiconductor substrate adjacent to the first semiconductor pattern, wherein the first and second semiconductor patterns may be doped with a second-type dopant, and the first semiconductor pattern may be between the channel region and the second semiconductor pattern.

A method of forming a semiconductor device according to example embodiments may include forming a gate pattern on a semiconductor substrate, the semiconductor substrate doped with a first-type dopant; forming a first semiconductor pattern in a first recess region in the semiconductor substrate, the first semiconductor pattern doped with a second-type dopant; and/or forming a second semiconductor pattern in a second recess region in the semiconductor substrate, the second semiconductor pattern doped with a second-type dopant, wherein the first semiconductor pattern may supply a compressive or tensile force to a channel region below the gate pattern.

### BRIEF DESCRIPTION OF THE DRAWINGS

FIG. 1 is a cross-sectional view of a semiconductor device according to example embodiments.

FIGS. 2 through 7 are cross-sectional views illustrating a method of forming a semiconductor device according to example embodiments.

### DETAILED DESCRIPTION OF EXAMPLE EMBODIMENTS

Example embodiments will now be described hereinafter in further detail with reference to the accompanying drawings. Examples, however, may be embodied in many different forms and should not be construed as limited to example embodiments set forth herein. Rather, example embodiments have been provided so that the disclosure will be more thorough and complete, and will better convey the scope of the disclosure to those skilled in the art. In the drawings, the thickness of layers and regions may have been exaggerated for clarity.

It will be understood that when an element or layer is referred to as being “on”, “connected to”, “coupled to”, or “covering” another element or layer, it may be directly on, connected to, coupled to, or covering the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

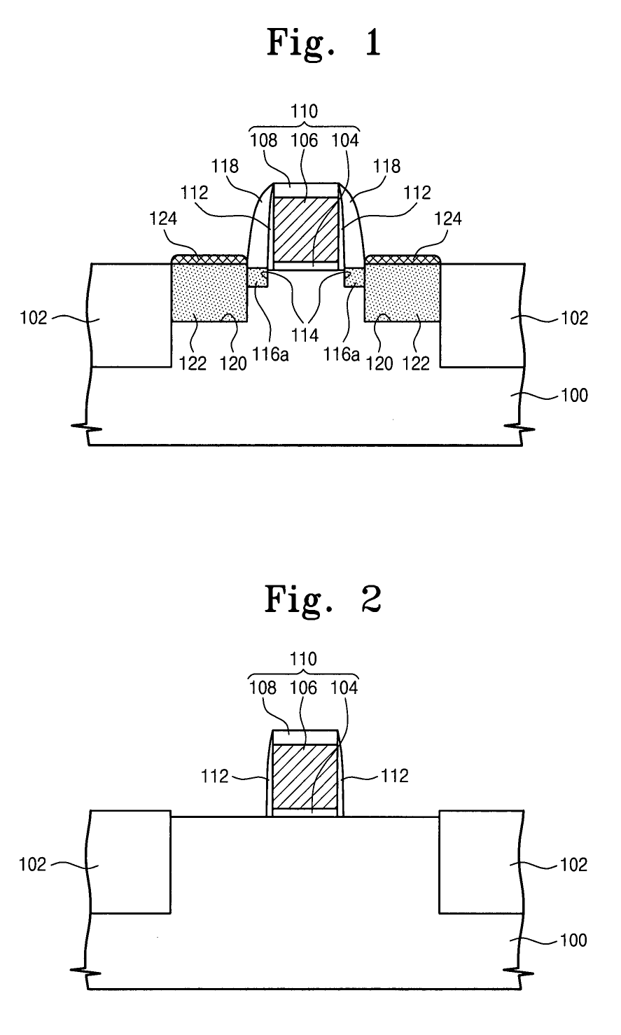

FIG. 1 is a cross-sectional view of a semiconductor device according to example embodiments. Referring to FIG. 1, a device isolation layer 102 may be disposed in a semiconductor substrate 100 to define an active region. The device isolation layer 102 may be a trench type isolation layer. The active region may be part of the semiconductor device and may be doped with dopants of a first type. The semiconductor substrate 100 may be a silicon substrate. A gate pattern 110 may be disposed on the active region of the semiconductor substrate 100. The gate pattern 110 may include a gate insulator 104 and a gate electrode 106 stacked on the gate insulator 104. The gate pattern 110 may further include a hard mask pattern 108 disposed on the gate electrode 106. The gate insulator 104 may include at least one material selected from the group consisting of an oxide, nitride, oxynitride, metal silicate, and high-k dielectric metal oxide (e.g., hafnium oxide, aluminum oxide). The gate electrode 106 may be made of a conductive material. For example, the gate electrode 106 may include at least one material selected from the group consisting of doped silicon, metal (e.g., tungsten, molybdenum), conductive metal nitride (e.g., titanium nitride, tantalum nitride), and metal silicide. The gate electrode 106 may be made of a conductive material having the desired work function. For example, where an NMOS transistor includes the gate electrode 106, the gate electrode 106 may be made of a conductive material having a work function that may be close to the conduction band of silicon. Where a PMOS transistor includes the gate electrode 106, the gate electrode 106 may be made of a conductive material having a work function that may be close to the valence band of silicon. The hard mask pattern 108 may be made of an insulating material having an etch selectivity with respect to the semiconductor substrate 100. In addition, the hard mask pattern 108 may be made of an insulating material having an etch selectivity with respect to the gate electrode 106. The hard mask pattern 108 may include at least one material selected from the group consisting of, for example, oxide, oxynitride, and nitride.

A gate spacer 118 may be disposed on opposite sidewalls of the gate pattern 110. The gate spacer 118 may include at least one material selected from the group consisting of oxide, oxynitride, and nitride. A first semiconductor pattern 116a may fill a first recess region 114 formed in the active region below the gate spacer 118. The bottom surface of the first recess region 114 may be disposed at a first depth from a top surface of the active region. The first semiconductor pattern 116a may be disposed beside a channel region in the active region below the gate pattern 110. For example, a pair of first semiconductor patterns 116a may be disposed on opposite sides of the channel region. The first semiconductor pattern 116a may exert a compressive force or a tensile force on the channel region.

A second semiconductor pattern 122 may fill a second recess region 120 formed in the active region beside the first semiconductor pattern 116a. The second recess region 120 may be deeper than the first recess region 114. For example, the bottom surface of the second recess region 120 may be disposed at a second depth from the top surface of the active region, wherein the second depth may be larger than the first depth of the first recess region 114. The first semiconductor pattern 116a may be interposed between the channel region and the second semiconductor pattern 122. A pair of first semiconductor patterns 116a and the channel region may be disposed between a pair of second semiconductor patterns 122. The semiconductor substrate 100 may be below the first semiconductor pattern 116a. The second semiconductor pattern 122 may be formed of a semiconductor having at least one IV-group element included in the first semiconductor pattern 116a.

The first and second semiconductor patterns 116a and 122 may be in lateral contact with each other. Because of the depths of the first and second recess regions 114 and 120, respectively, the first semiconductor pattern 116a may be in contact with an upper side of the second semiconductor pattern 122. Consequently, the first and second recess regions 114 and 120 may communicate with each other. The first and second semiconductor patterns 116a and 122 may constitute a source/drain region of a transistor. For example, the first semiconductor pattern 116a may correspond to an extension of the source/drain region, and the second semiconductor pattern 122 may correspond to a contact portion of the source/drain region. The contact portion of the source/drain region may be in contact with a contact structure.

The distance between the pair of second semiconductor patterns 122 may be increased by virtue of the presence of the pair of first semiconductor patterns 116a on opposite sides of the channel region. Consequently, the distance between the second semiconductor patterns 122 may be greater than the distance between the first semiconductor patterns 116a. The first and second semiconductor patterns 116a and 122 may be doped with second-type dopants. As a result, the first and second semiconductor patterns 116a and 122 may be electrically connected to each other. A dopant concentration of the first semiconductor pattern 116a may be lower than that of the second semiconductor pattern 122. Accordingly, the diffusion of the dopants from the first semiconductor pattern 116a to the channel region may be reduced or prevented, thus reducing or preventing the short channel effect.

An offset spacer 112 may be disposed between the gate spacer 118 and the sidewall of the gate pattern 110. The offset spacer 112 may be made of an insulating material. For example, the offset spacer 112 may be made of oxide, nitride, or oxynitride. A side surface of the first semiconductor pattern 116a adjacent to the channel region may be aligned with the offset spacer 112.

A metal-semiconductor compound layer 124 may be disposed on the second semiconductor pattern 122. The metal-semiconductor compound layer 124 may have a lower resistivity than the second semiconductor pattern 122. A contact structure configured to transmit an electrical signal to the source/drain region may be connected to the metal-semiconductor compound layer 124 so as to be electrically connected to the second semiconductor pattern 122. Consequently, the contact resistance between the contact structure and the second semiconductor pattern 122 may be decreased because of the metal-semiconductor compound layer 124. The metal-semiconductor compound layer 124 may be disposed to be higher than the top surface of the active region. For example, the bottom surface of the metal-semiconductor compound layer 124 may be disposed to be higher than the top surface of the active region. Therefore, it may be possible to reduce or prevent the diffusion of metal in the metal-semiconductor compound layer 124 from penetrating the channel region along the surface of the active region. Where the gate electrode 106 is made of doped silicon, the hard mask pattern 108 may be omitted and a metal silicide layer (not shown) may be disposed on the gate electrode 106. The metal silicide layer and the metal-semiconductor compound layer 124 may include the same metal. For example, the metal-semiconductor compound layer 124 may include cobalt, nickel, and/or titanium.

The first semiconductor pattern 116a may be disposed to supply a compressive force to the channel region. Where a compressive force is applied to the channel region, the mobility of holes migrating along a channel in the channel region may increase. Thus, a transistor, including the gate electrode 106 and the source/drain region (e.g., the first and second semiconductor patterns 116a and 122, respectively), may be a PMOS transistor. Consequently, the first-type dopants may be N-type dopants, and the second-type dopants may be P-type dopants. The gate electrode 106 may be made of a conductive material having a work function that may be relatively close to the valence band of silicon. For example, the gate electrode 106 may be made of silicon doped with P-type dopants or another conductive material having a work function that may be relatively close to the valence band.

To supply a compressive force to the channel region, the first semiconductor pattern 116a may be made of silicon germanium (SiGe) or germanium (Ge). Because the first semiconductor pattern 116a may include germanium, which has a larger atomic size than silicon, the first semiconductor pattern 116a may supply a compressive force to the channel region. In the first semiconductor pattern 116a, the percentage or proportion of germanium to the sum of silicon and germanium may be about 15˜100 percent. For example, a percentage of 100 percent means that the first semiconductor pattern 116a may be made essentially, if not entirely, of germanium. The proportion of germanium may be about 15 percent or more to supply a sufficient compressive force to the channel region. The germanium in the first semiconductor pattern 116a may reduce or prevent the diffusion of dopants from the first semiconductor pattern 116a to the channel region.

When the first semiconductor pattern 116a is made of silicon germanium or germanium, the second semiconductor pattern 122 may be made of a germanium-containing semiconductor. For example, the second semiconductor pattern 122 may be made of silicon germanium or germanium. The germanium concentration of the first semiconductor pattern 116a may be equal to or higher than that of the second semiconductor pattern 122. Thus, the first semiconductor pattern 116a may have the appropriate germanium concentration to supply a sufficient compressive force to the channel region. In the second semiconductor pattern 122, the percentage or proportion of germanium to the sum of silicon and germanium may be about 15˜100 percent.

Where the second semiconductor pattern 122 is made of silicon germanium, the metal-semiconductor compound layer 124 may be made of metal germanosilicide. For example, the metal-semiconductor compound layer 124 may be made of cobalt germanide, nickel germanide, or titanium germanide.

The first semiconductor pattern 116a may be disposed to supply a tensile force to the channel region. Where a tensile force is applied to the channel region, the mobility of carriers migrating along a channel formed in the channel region may increase. Thus, a transistor, including the gate electrode 106 and the first and second semiconductor patterns 116a and 122, may be an NMOS transistor. Consequently, the first-type dopants may be P-type dopants, and the second-type dopants may be N-type dopants. The gate electrode 106 may be made of a conductive material having a work function that may be relatively close to the conduction band of silicon. For example, the gate electrode 106 may be made of silicon doped with N-type dopants or another conductive material having a work function that may be relatively close to the conduction band.

To supply a tensile force to the channel region, the first semiconductor pattern 116a may be made of silicon carbide (SiC). In the first semiconductor pattern 116a, a percentage or proportion of carbon to the sum of silicon and carbon may be about 0.1˜10 percent. The second semiconductor pattern 122 may be also made of silicon carbide. The carbon concentration of the first semiconductor pattern 116a may be equal to or higher than that of the second semiconductor pattern 122. Thus, the first semiconductor pattern 116a may have the appropriate carbon concentration to supply sufficient tensile force to the channel region. In the second semiconductor pattern 122, the proportion of carbon to the sum of silicon and carbon may also be about 0.1˜10 percent. Where the first semiconductor pattern 116a is made of silicon carbide, the first semiconductor pattern 116a may be doped with N-type dopants, e.g., arsenic (As) or phosphorus (P). For example, the first semiconductor pattern 116a may be doped with phosphorus. Phosphorus may diffuse a lesser distance in silicon carbide. Consequently, phosphorus may diffuse a lesser distance in silicon carbide than in silicon. Accordingly, the diffusion of phosphorus from the first semiconductor pattern 116a to the channel region may be reduced or suppressed, thus reducing or preventing the short channel effect.

Although not shown in the figures, a buried doped region may be formed in the semiconductor substrate 100 below the second semiconductor pattern 122. The buried doped region may be doped with dopants of the same type (e.g., second type) as the second semiconductor pattern 122. The second semiconductor pattern 122 and the buried doped region may be connected to each other.

According to the above-described semiconductor device, a source/drain region adjacent to the gate pattern 110 may include a first semiconductor pattern 116a disposed to fill a first recess region 114 formed in the active region and a second semiconductor pattern 122 disposed to fill a second recess region 120 formed in the active region. The first recess region 114 may have a smaller depth than the second recess region 120, and the first semiconductor pattern 116a may be disposed adjacent to the channel region. Thus, the first semiconductor pattern 116a, which may have a smaller thickness than the second semiconductor pattern 122, may supply sufficient compressive or tensile force to the channel region. As a result, the mobility of carriers (e.g., electrons) or holes migrating along a channel of the channel region may be improved so as to increase the turn-on current of a transistor. A pair of second semiconductor patterns 122, each having a larger thickness than the first semiconductor pattern 116a, may be sufficiently spaced apart from each other to enhance a punchthrough characteristic between source/drain regions formed on opposite sides of the gate pattern 110.

A method of forming a semiconductor device according to example embodiments will be described below with reference to FIGS. 2 through 7. Referring to FIG. 2, a device isolation layer 102 may be formed in a semiconductor substrate 100 to define an active region, which may be a portion of the semiconductor substrate 100. The active region may be doped with first-type dopants. The active region may be doped by performing a process of forming a well.

A gate pattern 110 may be formed on the active region. The gate pattern 110 may include a gate insulator 104, a gate electrode 106, and a hard mask pattern (e.g., capping insulation pattern) 108, sequentially stacked on the semiconductor substrate 100. The hard mask pattern 108 may be made of an insulation material having an etch selectivity with respect to the semiconductor substrate 100. Materials for forming the gate insulator 104, the gate electrode 106, and the hard mask pattern 108 may be the same as described with reference to FIG. 1.

An offset spacer 112 may be formed on opposite sidewalls of the gate pattern 110. The offset spacer 112 may be made of an insulation material having an etch selectivity with respect to the semiconductor substrate 100. Before the formation of the offset spacer 112, a gate oxidation process may be performed for the semiconductor substrate 100 to form a thermal oxide layer (not shown) on the sidewalls of the gate electrode 106.

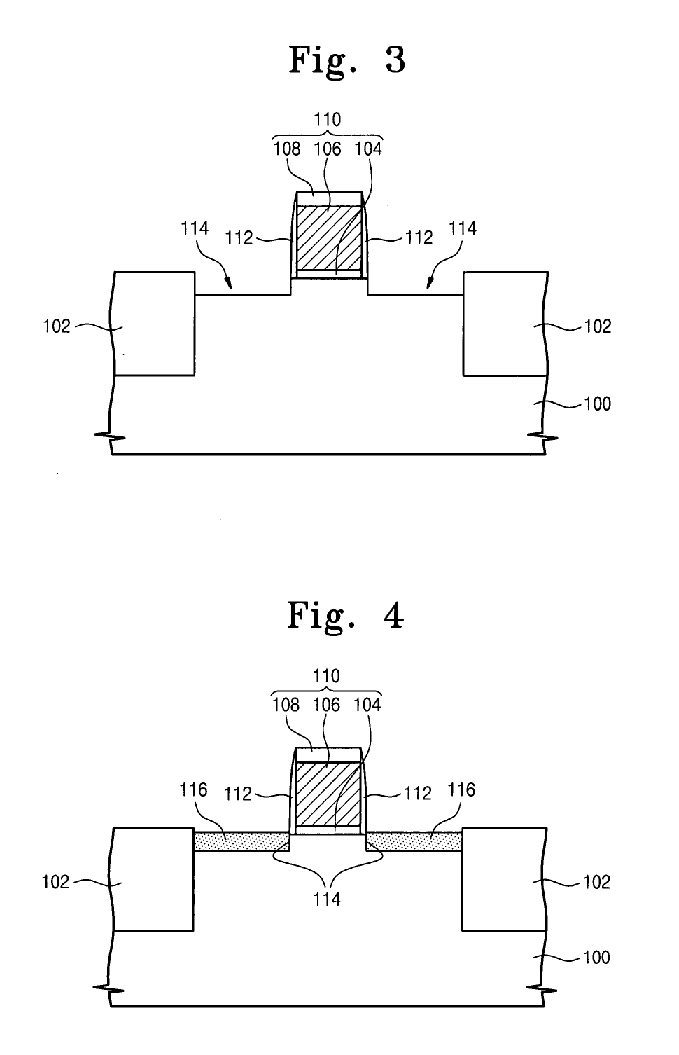

Referring to FIG. 3, using the gate pattern 110 and the offset spacer 112 as an etch mask, the active region may be etched to form a first recess region 114 having a first depth. The space between the first recess region 114 and a channel region below the gate pattern 110 may be controlled using the width of the offset spacer 112. Alternatively, the space between the first recess region 114 and the channel region may be controlled using the width of a thermal oxide layer (not shown) formed on a sidewall of the gate electrode 106 using a gate oxidation process. For example, where a thermal oxide layer is used, the offset spacer 112 may be omitted. Alternatively, the space between the first recess region 114 and the channel region may also be controlled by using both the width of a thermal oxide layer (not shown) and the width of the offset spacer 112. An anisotropic etch or an isotropic etch may be conducted to form the first recess region 114. As a result, the desired amount of space between the channel region and the first recess region 114 may be achieved.

Referring to FIG. 4, an undoped semiconductor layer 116 may be formed to fill the first recess region 114. The top surface of the undoped semiconductor layer 116 may be higher than that of the active region. The undoped semiconductor layer 116 may be formed to supply a compressive or tensile force to the channel region. The formation of the undoped semiconductor layer 116 may be achieved by a first selective epitaxial growth. Where the first recess region 114 is formed by an anisotropic etch, a surface treatment may be performed before the formation of the undoped semiconductor layer 116. Because of the surface treatment, etching damage of the surface of the first recess region 114 may be reduced or cured. The surface treatment may be a hydrogen treatment.

Where the undoped semiconductor layer 116 is formed to supply a compressive force to the channel region, the undoped semiconductor layer 116 may be formed of silicon germanium or germanium. The percentage or proportion of germanium to the sum of silicon and germanium in the undoped semiconductor layer 116 may be about 15˜100 percent. Where the undoped semiconductor layer 116 is formed to supply a tensile force to the channel region, the undoped semiconductor layer 116 may be formed of silicon carbide.

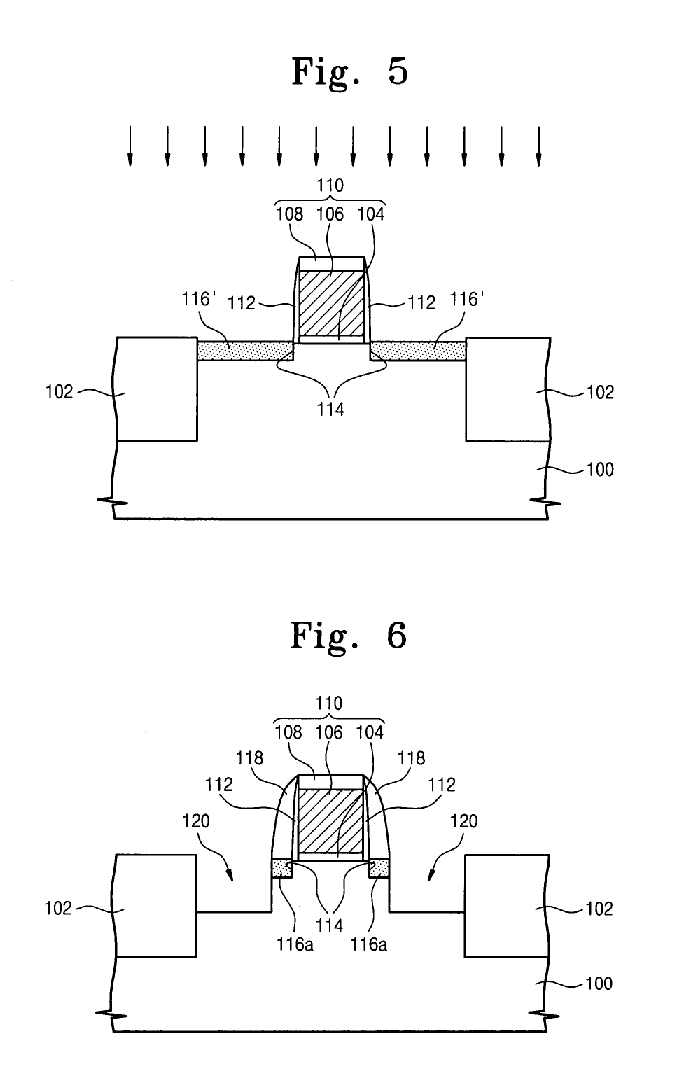

Referring to FIG. 5, using the gate pattern 110 and the offset spacer 112 as a mask, second-type dopants may be implanted into the undoped semiconductor layer 116 to form a doped semiconductor layer 116′. Where the doped semiconductor layer 116′ is formed to supply a compressive force to the channel region, the first-type dopants may be N-type dopants, and the second-type dopants may be P-type dopants. Where the doped semiconductor layer 116′ is formed to supply a tensile force to the channel region, the first-type dopants may be P-type dopants, and the second-type dopants may be N-type dopants. As described above, the doped semiconductor layer 116′ may be doped by ion implantation to reduce or prevent the diffusion of dopants into the channel region. Alternatively, the doped semiconductor layer 116′ may be doped by in-situ doping.

Referring to FIG. 6, a gate spacer 118 may be formed on the opposite sidewalls of the gate pattern 110. The gate spacer 118 may also cover the edge of the doped semiconductor layer 116′ adjacent to the gate pattern 110. Using the gate pattern 110 and the gate spacer 118 as an etch mask, the doped semiconductor layer 116′ and the active region may be successively etched to form a second recess region 120. The second recess region 120 may be formed to a second depth from the top surface of the active region. The second depth may be larger than the first depth of the first recess region 114. When the second recess region 120 is formed, a first semiconductor pattern 116a may be formed below the gate spacer 118. The first semiconductor pattern 116a may correspond to the remaining doped semiconductor layer 116′ below the gate spacer 118. A side surface of the first semiconductor pattern 116a may be exposed by the second recess region 120.

The width of the first semiconductor pattern 116a may be determined by the width of the gate spacer 118. The formation of the second recess region 120 may be achieved by anisotropic etch. Therefore, a pair of second recess regions 120 formed at opposite sides of the gate pattern 110 may be sufficiently spaced apart from each other. Alternatively, the formation of the second recess region 120 may be achieved by isotropic etch.

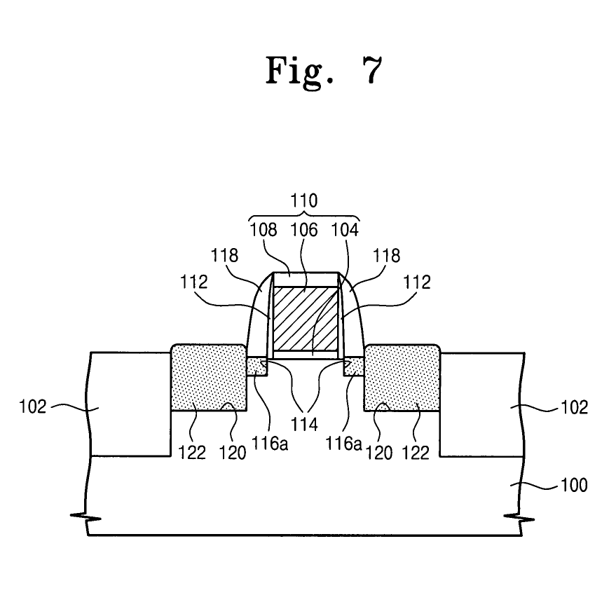

Referring to FIG. 7, a second semiconductor pattern 122 may be formed to fill the second recess region 120. The second semiconductor pattern 122 may be in contact with the exposed side surface of the first semiconductor pattern 116a. A bottom side surface of the second semiconductor pattern 122 may be in contact with an inner side surface of the second recess region 120. The second semiconductor pattern 122 may be formed of a semiconductor having at least one of the IV-group elements included in the first semiconductor pattern 116a. Where the first semiconductor pattern 116a is formed of silicon germanium or germanium, the second semiconductor pattern 122 may be formed of silicon germanium or germanium. The germanium concentration of the first semiconductor pattern 116a may be equal to or higher than that of the second semiconductor pattern 122. Where the first semiconductor pattern 116a is formed of silicon carbide (SiC), the second semiconductor pattern 122 may be formed of silicon carbide. The carbon concentration of the first semiconductor pattern 116a may be equal to or higher than that of the second semiconductor pattern 122. The percentage or proportion of germanium or carbon in the first and second semiconductor patterns 116a and 122, respectively, may be the same as described above and will not be discussed in further detail.

The formation of the second semiconductor pattern 122 may be achieved by a second selective epitaxial growth. Where the second recess region 120 is anisotropically etched, a surface treatment (e.g., hydrogen treatment) may be performed to reduce or cure the etching damage of the surface of the second recess region 120 before the formation of the second semiconductor pattern 122. The second semiconductor pattern 122 may be doped with second-type dopants. The doping of the second semiconductor pattern 122 may be achieved by in-situ doping. The top surface of the second semiconductor pattern 122 may protrude so as to be higher than the top surface of the active region.

Before or after the formation of the second semiconductor pattern 122, second-type dopants may be implanted using the gate pattern 110 and the gate spacer 118 as a mask to form a buried doped region (not shown) in the active region below the second recess region 120. The buried doped region may be in contact with the bottom surface of the second semiconductor pattern 122.

A metal layer (not shown) may be formed on the semiconductor substrate 100, including the second semiconductor pattern 122, and an annealing process may be performed to allow the metal layer and the second semiconductor pattern 122 to react to each other. The reaction of the metal layer with the second semiconductor pattern 122 may result in the formation of the metal-semiconductor compound layer 124, as illustrated in FIG. 1. The non-reacted portion of the metal layer may be removed. Thus, a semiconductor device as illustrated in FIG. 1 may be achieved. The metal layer may be formed of cobalt, nickel, and/or titanium. Where the gate electrode 106 is formed of doped silicon, a process of exposing the top surface of the gate electrode 106 may be performed to remove the hard mask pattern 108.before the formation of the metal layer. A metal silicide layer (not shown) may be formed on the gate electrode 106 when the metal-semiconductor compound layer 124 is formed. The process of forming the metal layer and performing the annealing process may be conducted in-situ.

As explained above, source/drain regions formed on opposite sides of a gate pattern may include a first semiconductor pattern and a second semiconductor pattern formed in an active region to fill a first recess region and a second recess region, respectively. The first recess region may be formed to have a smaller thickness than the second recess region and may be disposed adjacent to a channel region below the gate pattern. Accordingly, the first semiconductor pattern may supply sufficient compressive or tensile force to the channel region. Thus, the mobility of holes or carriers along a channel formed in the channel region may be improved so as to increase the turn-on current of a transistor. A pair of second semiconductor patterns may be disposed at opposite sides of the channel region. The pair of second semiconductor patterns may be sufficiently spaced apart from each other. As a result, a punchthrough characteristic between the source/drain regions disposed at opposite sides of the gate pattern may be enhanced.

While example embodiments have been disclosed herein, it should be understood that other variations may be possible. Such variations are not to be regarded: as a departure from the spirit and scope of example embodiments of the present disclosure, and all such modifications as would be obvious to one skilled in the art are intended to be included within the scope of the following claims.

What is claimed is:

1. A semiconductor device, comprising:
a gate pattern on a semiconductor substrate, the semiconductor substrate doped with a first-type dopant;
a first semiconductor pattern in the semiconductor substrate, the first semiconductor pattern supplying a compressive or tensile force to a channel region below the gate pattern; and
a second semiconductor pattern in the semiconductor substrate adjacent to the first semiconductor pattern;
wherein the first and second semiconductor patterns are doped with a second-type dopant, and the first semiconductor pattern is between the channel region and the second semiconductor pattern.

2. The semiconductor device of claim 1, wherein
the first semiconductor pattern supplies a compressive force to the channel region;
the first-type dopant is a N-type dopant, and the second-type dopant is a P-type dopant; and
the first semiconductor pattern is made of silicon germanium or germanium, and the second semiconductor pattern is made of silicon germanium or germanium.

3. The semiconductor device of claim 2, wherein the concentration of germanium in the first semiconductor pattern is equal to or higher than the concentration of germanium in the second semiconductor pattern.

4. The semiconductor device of claim 1, wherein
the first semiconductor pattern supplies a tensile force to the channel region,
the first-type dopant is a P-type dopant, and the second-type dopant is a N-type dopant; and
the first and second semiconductor patterns are made of silicon carbide.

5. The semiconductor device of claim 4, wherein the concentration of carbon in the first semiconductor pattern is equal to or higher than the concentration of carbon in the second semiconductor pattern.

6. The semiconductor device of claim 1, wherein the concentration of dopant in the first semiconductor pattern is lower than the concentration of dopant in the second semiconductor pattern.

7. The semiconductor device of claim 1, further comprising:
an offset spacer on a sidewall of the gate pattern and a gate spacer on the offset spacer.

8. The semiconductor device of claim 1, further comprising:
a metal-semiconductor compound layer on the second semiconductor pattern.

9. The semiconductor device of claim 8, wherein the metal-semiconductor compound layer is higher than a top surface of the semiconductor substrate.

10. A method of forming a semiconductor device, comprising:
forming a gate pattern on a semiconductor substrate, the semiconductor substrate doped with a first-type dopant;
forming a first semiconductor pattern in a first recess region in the semiconductor substrate, the first semiconductor pattern doped with a second-type dopant; and
forming a second semiconductor pattern in a second recess region in the semiconductor substrate, the second semiconductor pattern doped with a second-type dopant,
wherein the first semiconductor pattern supplies a compressive or tensile force to a channel region below the gate pattern.

11. The method of claim 10, wherein
the first semiconductor pattern supplies a compressive force to the channel region,
the first-type dopant is a N-type dopant, and the second-type dopant is a P-type dopant; and
the first semiconductor pattern is made of silicon germanium or germanium, and the second semiconductor pattern is made of silicon germanium or germanium.

12. The method of claim 11, wherein the concentration of germanium in the first semiconductor pattern is equal to or higher than the concentration of germanium in the second semiconductor pattern.

13. The method of claim 10, wherein
the first semiconductor pattern supplies a tensile force to the channel region,
the first-type dopant is a P-type dopant, and the second-type dopant is a N-type dopant; and
the first and second semiconductor patterns are made of silicon carbide.

14. The method of claim 13, wherein the concentration of carbon in the first semiconductor pattern is equal to or higher than the concentration of carbon in the second semiconductor pattern.

15. The method of claim 10, further comprising:
forming an offset spacer on a sidewall of the gate pattern before forming the first semiconductor pattern in the first recess region,
wherein the first recess region is formed by performing an etch using the gate pattern and the offset spacer as a mask.

16. The method of claim 10, wherein forming the first semiconductor pattern includes:
forming a semiconductor layer in the first recess region by selective epitaxial growth; and
implanting second-type dopant ions into the semiconductor layer using the gate pattern as a mask.

17. The method of claim 10, wherein the concentration of dopant in the first semiconductor pattern is lower than the concentration of dopant in the second semiconductor pattern.

18. The method of claim 10, wherein the second semiconductor pattern is formed by selective epitaxial growth.

19. The method of claim 10, wherein the second semiconductor pattern is doped by in-situ doping.

20. The method of claim 10, further comprising:
forming a metal layer on the semiconductor substrate after forming the second semiconductor pattern;
reacting the metal layer with the second semiconductor pattern to form a metal-semiconductor compound layer; and
removing the portion of the metal layer not reacted with the second semiconductor pattern.

21. The method of claim 20, wherein the metal-semiconductor compound layer is higher than a top surface of the semiconductor substrate.
